(19) United States
(12) Patent Application Publication
(10) Pub. No.: US 2026/0155804 A1
(43) Pub. Date: Jun. 4, 2026

(54) COMMUNICATION DEVICE

(71) Applicant: Panasonic Automotive Systems Co., Ltd., Kanagawa (JP)

(72) Inventors: Shunsuke KATSUMURA, Tokyo (JP); Tatsuya INOUE, Osaka (JP); Hideaki TOKUNAGA, Osaka (JP); Keiji KOBAYASHI, Osaka (JP); Kenji NOZOE, Fukui (JP)

(73) Assignee: Panasonic Automotive Systems Co., Ltd., Kanagawa (JP)

(21) Appl. No.: 19/318,958

(22) Filed: Sep. 4, 2025

(30) Foreign Application Priority Data
Nov. 29, 2024 (JP) 2024-208959

(51) Int. Cl. H03H 7/06; H04L 25/02

(52) U.S. Cl. CPC H03H 7/06; H04L 25/0272

(57) ABSTRACT

A communication device performs data transmission according to a differential transmission method. The communication device includes a first common mode noise filter including a first coil, a second coil, and a third coil, a communication control circuit that transmits and receives a signal through a first line connected to the first coil and a second line connected to the second coil, and at least one resistor that has a first end connected to the third coil and a second end connected to GND, and that is disposed outside the first common mode noise filter.

### TECHNICAL FIELD

The present disclosure relates to a communication device.

### BACKGROUND ART

It is required to prevent reflection of common mode noise. Patent Literature 1 discloses the following common mode noise filter. That is, a first signal coil inserted and connected to one differential signal line is formed in a spiral shape in a dielectric layer of a multilayer structure, and a second signal coil inserted and connected to the other differential signal line is formed in the dielectric layer to face the first signal coil interposing the dielectric layer. In the dielectric layer, a control coil wound in a direction that is the same as that of the first signal coil is formed to be sandwiched between the first and second signal coils via the dielectric layer. An embedded resistor is connected to at least one of an outer peripheral end and an inner peripheral end of the control coil. The control coil and the embedded resistor form a feedback loop circuit.

### CITATION LIST

### Patent Literature

Patent Literature 1: WO2015/181883

### SUMMARY OF INVENTION

However, since Patent Literature 1 has a configuration in which the embedded resistor is provided inside the common mode noise filter, the embedded resistor may not be able to withstand heat generated by a current flowing through the embedded resistor during generation of common mode noise, an immunity test, or the like.

An object of the present disclosure is to provide a communication device including a common mode noise filter and having improved heat resistance.

One aspect of the present disclosure provides a communication device that performs data transmission according to a differential transmission method. The communication device includes a first common mode noise filter including a first coil, a second coil, and a third coil; a communication control circuit that transmits and receives a signal through a first line connected to the first coil and a second line connected to the second coil; and at least one resistor that has a first end connected to the third coil and a second end connected to GND, and that is disposed outside the first common mode noise filter.

According to the present disclosure, it is possible to provide a communication device including a common mode noise filter and having improved heat resistance.

### BRIEF DESCRIPTION OF DRAWINGS

FIG. 1 is a diagram showing an example of a configuration of a communication system 1A according to Embodiment 1;

FIG. 2 is a graph showing a transmission characteristic of a differential transmission line in a configuration in which a resistor 51A and a resistor 51B of a communication device 10A shown in FIG. 1 are not disposed;

FIG. 3 is a graph showing a transmission characteristic of a differential transmission line in a configuration in which the resistor 51A and the resistor 51B are disposed in the communication device 10A as shown in FIG. 1;

FIG. 4 is a graph showing a value of current flowing through the resistor 51A and the resistor 51B when a resistance value of the resistor 51A and the resistor 51B is 0.1Ω in the configuration of the communication system 1A shown in FIG. 1;

FIG. 5 is a graph showing a value of current flowing through the resistor 51A and the resistor 51B when the resistance value of the resistor 51A and the resistor 51B is 1Ω in the configuration of the communication system 1A shown in FIG. 1;

FIG. 6 is a graph showing a value of current flowing through the resistor 51A and the resistor 51B when the resistance value of the resistor 51A and the resistor 51B is 50Ω in the configuration of the communication system 1A shown in FIG. 1;

FIG. 7 is a graph showing a value of current flowing through the resistor 51A and the resistor 51B when the resistance value of the resistor 51A and the resistor 51B is 100Ω in the configuration of the communication system 1A shown in FIG. 1;

FIG. 8 is a graph showing a value of current flowing through the resistor 51A and the resistor 51B when the resistance value of the resistor 51A and the resistor 51B is 1 kΩ in the configuration of the communication system 1A shown in FIG. 1;

FIG. 9 is a graph showing a value of current flowing through the resistor 51A and the resistor 51B when the resistance value of the resistor 51A and the resistor 51B is 10 kΩ in the configuration of the communication system 1A shown in FIG. 1;

FIG. 10 shows a first modification of a configuration of a CMNF and resistors according to Embodiment 1;

FIG. 11 shows a second modification of the configuration of a CMNF and resistors according to Embodiment 1;

FIG. 12 is a diagram showing an example of a configuration of a communication system 1B according to Embodiment 2;

FIG. 13 is a graph showing a transmission characteristic of a differential transmission line in a configuration in which the resistor 51A and the resistor 51B of a communication device 10C shown in FIG. 12 are not disposed;

FIG. 14 is a graph showing a transmission characteristic of a differential transmission line in a configuration in which the resistor 51A and the resistor 51B are disposed in the communication device 10C as shown in FIG. 12;

FIG. 15 is a graph showing a value of current flowing through the resistor 51A and the resistor 51B when the resistance value of the resistor 51A and the resistor 51B is 0.1Ω in the configuration of the communication system 1B shown in FIG. 12;

FIG. 16 is a graph showing a value of current flowing through the resistor 51A and the resistor 51B when the resistance value of the resistor 51A and the resistor 51B is 1Ω in the configuration of the communication system 1B shown in FIG. 12;

FIG. 17 is a graph showing a value of current flowing through the resistor 51A and the resistor 51B when the resistance value of the resistor 51A and the resistor 51B is 50Ω in the configuration of the communication system 1B shown in FIG. 12;

FIG. 18 is a graph showing a value of current flowing through the resistor 51A and the resistor 51B when the resistance value of the resistor 51A and the resistor 51B is 100Ω in the configuration of the communication system 1B shown in FIG. 12;

FIG. 19 is a graph showing a value of current flowing through the resistor 51A and the resistor 51B when the resistance value of the resistor 51A and the resistor 51B is 1 kΩ in the configuration of the communication system 1B shown in FIG. 12; and

FIG. 20 is a graph showing a value of current flowing through the resistor 51A and the resistor 51B when the resistance value of the resistor 51A and the resistor 51B is 10 kΩ in the configuration of the communication system 1B shown in FIG. 12.

### DESCRIPTION OF EMBODIMENTS

Hereinafter, an embodiment of the present disclosure will be described in detail with reference to the drawings as appropriate. However, unnecessarily detailed description may be omitted. For example, detailed description of already well-known matters and redundant description of substantially the same configuration may be omitted. This is to avoid unnecessary redundancy of the following description and to facilitate understanding of those skilled in the art. The accompanying drawings and the following description are provided for those skilled in the art to sufficiently understand the present disclosure, and are not intended to limit the subject matter described in claims.

### Embodiment 1

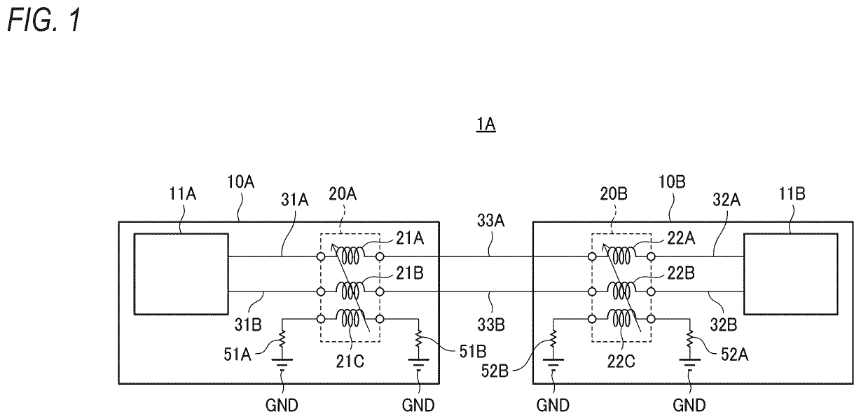

FIG. 1 is a diagram showing an example of a configuration of a communication system according to Embodiment 1. FIG. 1 shows a configuration of an equivalent circuit of the communication system.

A communication system 1A includes a communication device 10A and a communication device 10B. The communication device 10A and the communication device 10B are connected by a transmission cable, and transmit and receive data according to a differential transmission method through the transmission cable.

The communication system 1A may be used when an in-vehicle camera mounted on a vehicle and an electronic control unit (ECU) are connected by a transmission cable. Alternatively, the communication system 1A may be used in various systems in which two or more electronic devices are connected by a transmission cable.

The communication device 10A includes a communication control circuit 11A, a line 31A, a line 31B, a CMNF 20A, a resistor 51A, and a resistor 51B. CMNF is an abbreviation for common mode noise filter. The common mode noise filter may be read as a common mode choke coil.

The communication control circuit 11A is a circuit that controls transmission and reception of data performed according to the differential transmission method. The communication control circuit 11A may be a semiconductor integrated circuit, and may be, for example, a large scale integration (LSI), an application specific integrated circuit (ASIC), a field programmable gate array (FPGA), or the like. Although not described herein, the communication control circuit 11A may be connected to a predetermined processor and controlled by the processor.

The CMNF 20A includes a coil 21A, a coil 21B, and a coil 21C. The coil 21A and the coil 21B are wound in the same direction. The coil 21A, the coil 21B, and the coil 21C are configured to be magnetically coupled to each other. A physical configuration of the CMNF 20A may be a configuration in which the coil 21A, the coil 21B, and the coil 21C are stacked with a dielectric layer or a magnetic layer interposed therebetween, as disclosed in Patent Literature 1.

A first end of the line 31A is connected to the communication control circuit 11A, and a second end of the line 31A is connected to a first end of the coil 21A of the CMNF 20A.

A first end of the line 31B is connected to the communication control circuit 11A, and a second end of the line 31B is connected to a first end of the coil 21B of the CMNF 20A.

The communication device 10B includes a communication control circuit 11B, a line 32A, a line 32B, a CMNF 20B,] a resistor 52A, and a resistor 52B.

Since the communication control circuit 11B is similar to the communication control circuit 11A, description thereof will be omitted.

The CMNF 20B includes a coil 22A, a coil 22B, and a coil 22C. The coil 22A, the coil 22B, and the coil 22C are configured to be magnetically coupled to each other. A physical configuration of the CMNF 20B may be a configuration in which the coil 22A, the coil 22B, and the coil 22C are stacked with a dielectric layer or a magnetic layer interposed therebetween, as disclosed in Patent Literature 1.

A first end of the line 32A is connected to the communication control circuit 11B, and a second end of the line 32A is connected to a first end of the coil 22A of the CMNF 20B.

A first end of the line 32B is connected to the communication control circuit 11B, and a second end of the line 32B is connected to a first end of the coil 22B of the CMNF 20B.

The communication device 10A and the communication device 10B are connected by a line 33A and a line 33B that form a transmission cable.

A first end of the line 33A is connected to a second end of the coil 21A of the CMNF 20A, and a second end of the line 33A is connected to a second end of the coil 22A of the CMNF 20B.

A first end of the line 33B is connected to a second end of the coil 21B of CMNF 20A, and a second end of the line 33B is connected to a second end of the coil 22B of CMNF 20B.

The line 31A, the coil 21A of the CMNF 20A, the line 33A, the coil 22A of the CMNF 20B, and the line 32A may be referred to as a first transmission line. The line 31B, the coil 21B of the CMNF 20A, the line 33B, the coil 22B of the CMNF 20B, and the line 32B may be referred to as a second transmission line. The first transmission line and the second transmission line may be collectively referred to as a differential transmission line.

The communication control circuit 11A and the communication control circuit 11B transmit and receive data according to the differential transmission method using the first transmission line and the second transmission line. The CMNF 20A and the CMNF 20B may be common mode noise filters for Mipi C-PHY. Therefore, a maximum communication speed of about 6 Gbps may be achieved between the communication control circuit 11A and the communication control circuit 11B.

When data is transmitted from the communication control circuit 11A to the communication control circuit 11B, the communication control circuit 11A may be referred to as a transmitter, and the communication control circuit 11B may be referred to as a receiver. When data is transmitted from the communication control circuit 11B to the communication control circuit 11A, the communication control circuit 11B may be referred to as a transmitter, and the communication control circuit 11A may be referred to as a receiver.

By providing the CMNF 20A and the CMNF 20B, it is possible to prevent common mode noise from emitting from the line 33A and the line 33B. However, in the line 31A and the line 31B between the CMNF 20A and the communication control circuit 11A or the line 32A and the line 32B between the CMNF 20B and the communication control circuit 11B, the common mode noise may be reflected, and due to an influence thereof, at least one of the line 31A, the line 31B, the line 32A, and the line 32B may emit the common mode noise. The emission of the common mode noise adversely affects an operation of an electronic circuit or the like positioned nearby, and thus it is necessary to prevent the emission of the common mode noise. An emission test for testing whether such emission of the common mode noise is prevented is performed. In the present embodiment, a communication device capable of preventing the emission of the common mode noise by preventing occurrence of the reflection of the common mode noise will be described. This will be described in detail below.

As described above, the CMNF 20A includes the coil 21C in addition to the coil 21A and the coil 21B. A first end of the coil 21C is connected to a first end of the resistor 51A. A second end of the resistor 51A is connected to GND. A second end of the coil 21C is connected to a first end of the resistor 51B. A second end of the resistor 51B is connected to GND. The resistor 51A and the resistor 51B are disposed not inside the CMNF 20A but outside the CMNF 20A. A resistance value of the resistor 51A and a resistance value of the resistor 51B may be equal. However, the resistance value of the resistor 51A and the resistance value of the resistor 51B may be different. The resistance value of one of the resistor 51A and the resistor 51B may be 0Ω.

As described above, the CMNF 20B includes the coil 22C in addition to the coil 22A and the coil 22B. A first end of the coil 22C is connected to a first end of the resistor 52A. A second end of the resistor 52A is connected to GND. A second end of the coil 22C is connected to a first end of the resistor 52B. A second end of the resistor 52B is connected to GND. The resistor 52A and the resistor 52B are disposed not inside the CMNF 20B but outside the CMNF 20B. A resistance value of the resistor 52A and a resistance value of the resistor 52B may be equal. However, the resistance value of the resistor 52A and the resistance value of the resistor 52B may be different. The resistance value of one of the resistor 52A and the resistor 52B may be 0Ω.

Next, operations of the CMNF 20A, the resistor 51A, and resistor 51B will be described. Since operations of the CMNF 20B, the resistor 52A, and the resistor 52B are the same as the operations of the CMNF 20A, the resistor 51A, and resistor 51B, the description thereof will be omitted.

In a differential mode, since the coil 21A and the coil 21B of the CMNF 20A have opposite polarities, potentials of the coil 21A and the coil 21B are offset, and an average potential of the potentials of the coil 21A and the coil 21B becomes zero.

In a common mode, since both the coil 21A and the coil 21B of the CMNF 20A have the same polarity, an average potential of potentials of the coil 21A and the coil 21B does not become zero. Therefore, an electromagnetic field corresponding to the average potential is applied to the coil 21C, and an induced electromotive force is generated in the coil 21C. The common mode noise is generated as current in the coil 21C by the induced electromotive force. The current generated in the coil 21C is consumed as heat in the resistor 51A and the resistor 51B connected to the outside of the CMNF 20A. As a result, since the common mode noise is absorbed and reduced, it is possible to prevent the reflection of the common mode noise that has previously occurred between the CMNF 20A and the communication control circuit 11A.

In addition, in the present embodiment, since the resistor 51A and the resistor 51B are disposed outside the CMNF 20A, the CMNF 20A is less likely to be affected even when the heat generation increases as compared with a case in which a resistor is disposed inside the CMNF 20A. That is, by the configuration illustrated in FIG. 1, it is possible to achieve the communication device 10A and the communication device 10B having improved heat resistance and including the common mode noise filter.

### Verification for Transmission Characteristic

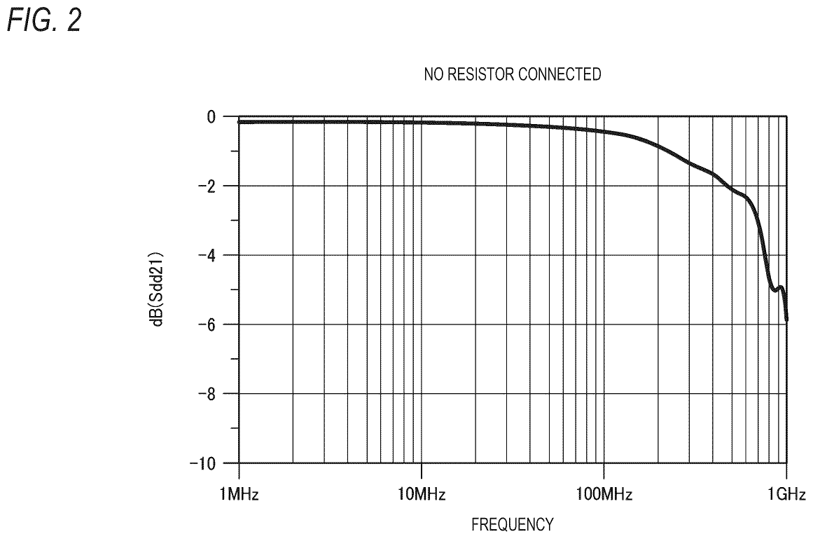

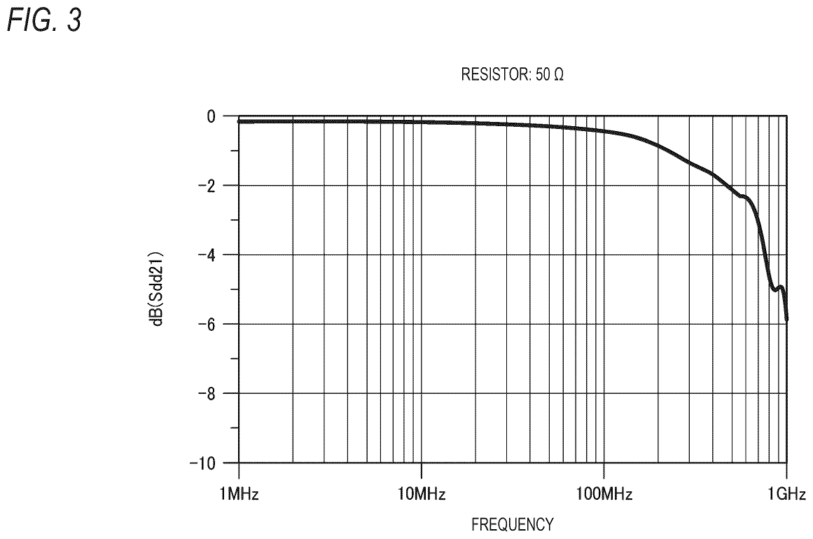

Next, with reference to FIGS. 2 and 3, it will be described that the configurations of the communication device 10A and the communication device 10B shown in FIG. 1 are less likely to affect the transmission characteristic of the differential transmission line.

FIG. 2 is a graph showing the transmission characteristic of the differential transmission line in a configuration in which the resistor 51A and the resistor 51B of the communication device 10A shown in FIG. 1 are not disposed. FIG. 3 is a graph showing the transmission characteristic of the differential transmission line in a configuration in which the resistor 51A and resistor 51B are disposed in the communication device 10A as shown in FIG. 1. In each of the graphs shown in FIGS. 2 and 3, a horizontal axis represents frequency, and a vertical axis represents intensity of the Sdd21 transmission characteristic. FIG. 3 is a graph when a resistance value of the resistor 51A and the resistor 51B is 50Ω.

When FIG. 2 and FIG. 3 are compared, the transmission characteristic is almost unchanged between a case in which the resistor 51A and the resistor 51B are not disposed and a case in which the resistor 51A and the resistor 51B are disposed. That is, it can be seen that even when the resistor 51A and the resistor 51B are disposed, the transmission characteristic is less likely to be affected.

### Verification for Resistance Value

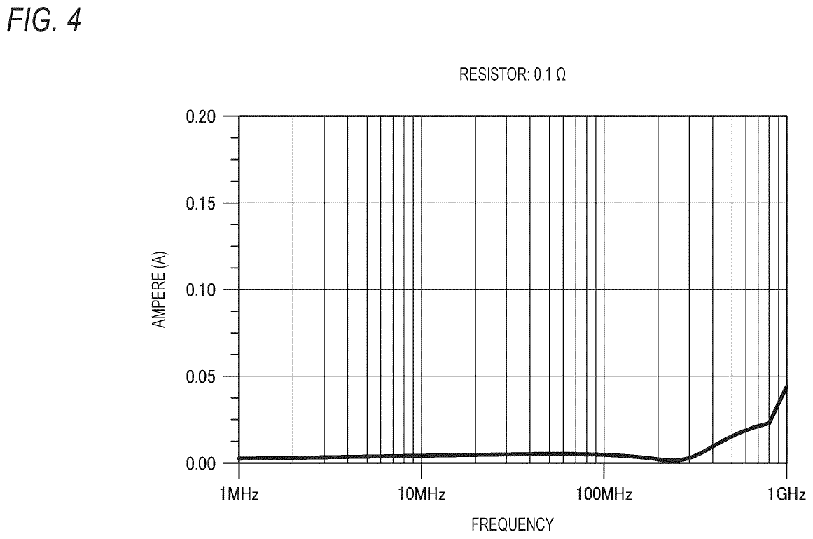

Next, a relation between the resistance value of the resistor 51A and resistor 51B and an effect of preventing the common mode noise will be described with reference to FIGS. 4 to 9.

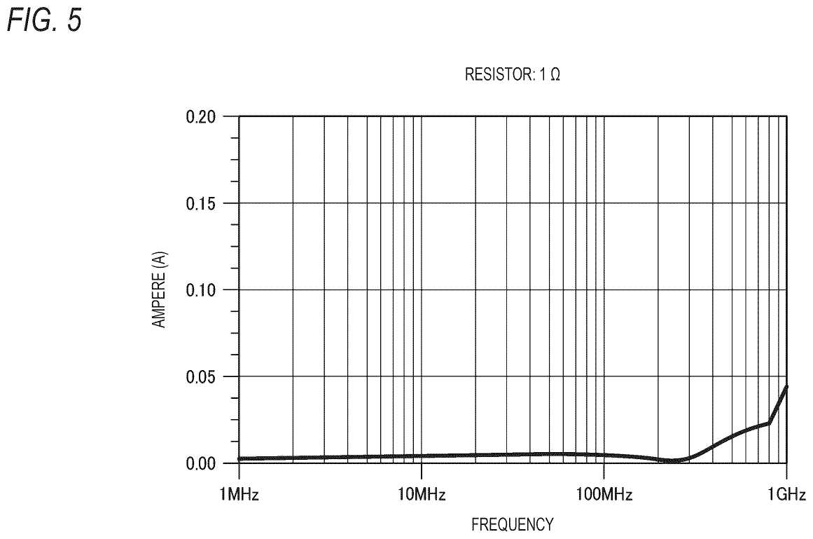

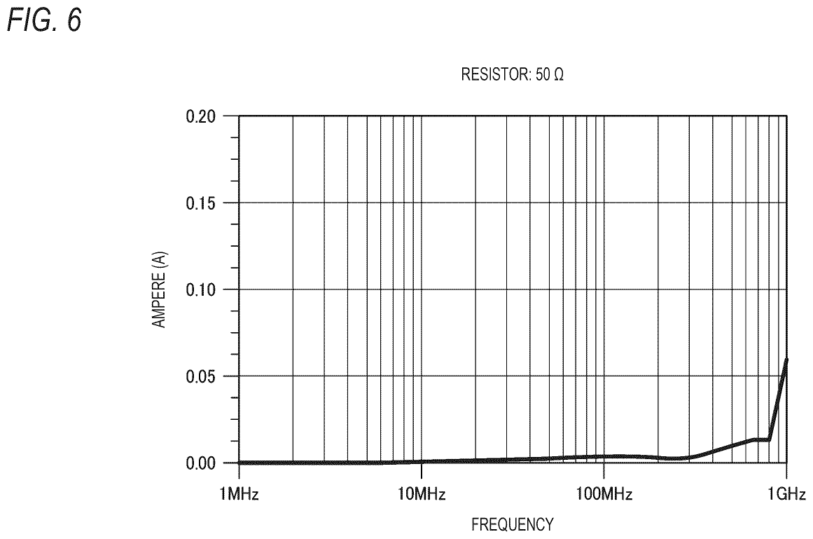

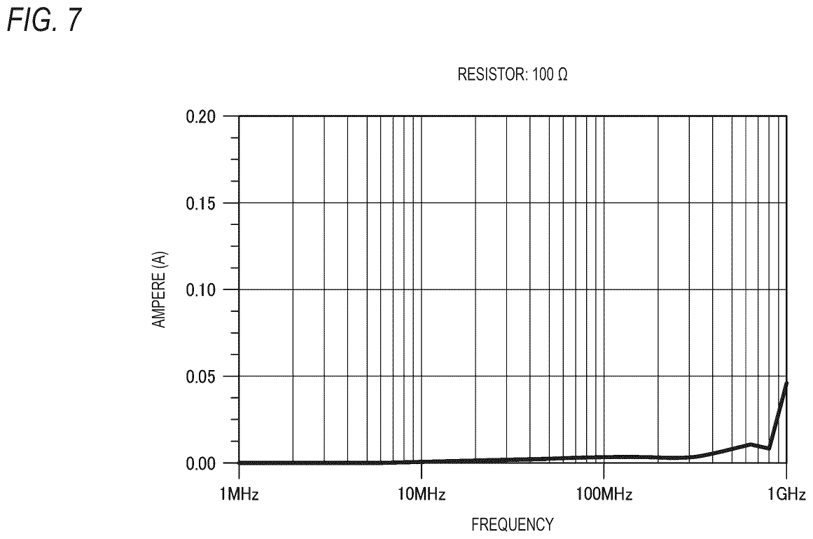

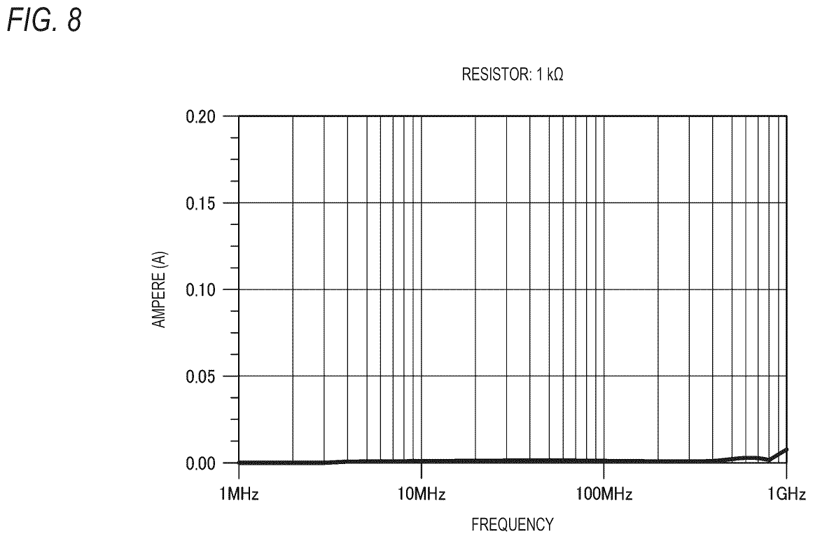

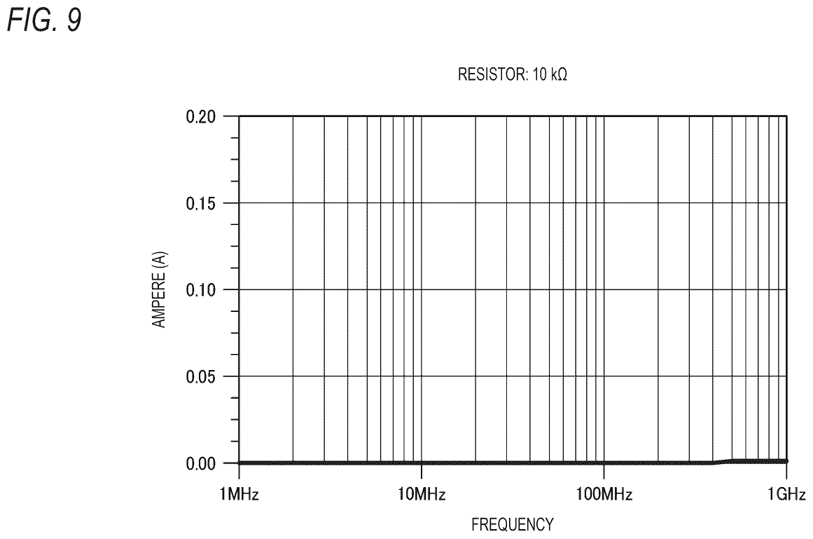

FIG. 4 is a graph showing a value of current flowing through the resistor 51A and the resistor 51B when the resistance value of the resistor 51A and the resistor 51B is 0.1Ω in the configuration of the communication system 1A shown in FIG. 1. FIG. 5 is a graph showing a value of current flowing through the resistor 51A and the resistor 51B when the resistance value of the resistor 51A and the resistor 51B is 1Ω in the configuration of the communication system 1A shown in FIG. 1. FIG. 6 is a graph showing a value of current flowing through the resistor 51A and the resistor 51B when the resistance value of the resistor 51A and the resistor 51B is 50Ω in the configuration of the communication system 1A shown in FIG. 1. FIG. 7 is a graph showing a value of current flowing through the resistor 51A and the resistor 51B when the resistance value of the resistor 51A and the resistor 51B is 100Ω in the configuration of the communication system 1A shown in FIG. 1. FIG. 8 is a graph showing a value of current flowing through the resistor 51A and the resistor 51B when the resistance value of the resistor 51A and the resistor 51B is 1 kΩ in the configuration of the communication system 1A shown in FIG. 1. FIG. 9 is a graph showing a value of current flowing through the resistor 51A and the resistor 51B when the resistance value of the resistor 51A and the resistor 51B is 10 kΩ in the configuration of the communication system 1A shown in FIG. 1. In each of the graphs shown in FIGS. 4 to 9, a horizontal axis represents frequency, and a vertical axis represents the current value (ampere).

As shown in FIGS. 4 to 8, it can be seen that in a case in which the resistance value of the resistor 51A and the resistor 51B is 0.1Ω to 1 kΩ, when the common mode noise of 100 MHz or more occurs, the induced electromotive force is generated in the coil 21C and current flows through the resistor 51A and the resistor 51B. That is, it can be seen that the reflection of the common mode noise is prevented by consuming the common mode noise as heat by the resistor 51A and the resistor 51B.

It can be seen that even when the resistance value of the resistor 51A and the resistor 51B connected to the coil 21C of the CMNF 20A is a relatively small value such as 0.1Ω, a sufficient effect of preventing the reflection of the common mode noise is exhibited.

As shown in FIG. 9, when the resistance value of the resistor 51A and resistor 51B is 10 kΩ, almost no current flows through the resistor 51A and resistor 51B.

That is, in the configuration of the communication device 10A shown in FIG. 1, the resistance value of the resistor 51A and the resistor 51B may be in a range of more than 0Ω and 1 kΩ or less. However, the resistance value of the resistor 51A and the resistor 51B are not limited to the range. The same applies to the resistor 52A and the resistor 52B of the communication device 10B.

### Modification

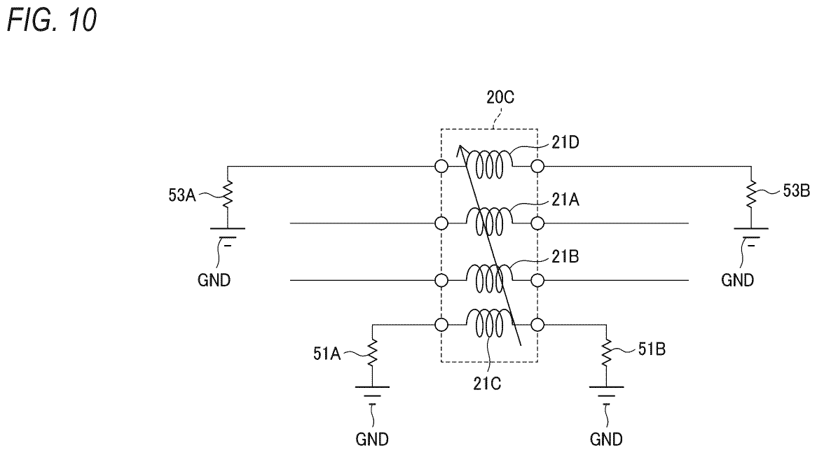

FIG. 10 is a diagram showing a first modification of the configuration of a CMNF and resistors according to Embodiment 1. FIG. 10 shows a configuration of an equivalent circuit of the CMNF and the resistors.

As shown in FIG. 10, a CMNF 20C includes a coil 21D in addition to the coil 21A, the coil 21B, and the coil 21C. The coil 21A and the coil 21B are wound in the same direction. The coil 21A, the coil 21B, the coil 21C, and the coil 21D are configured to be magnetically coupled to each other.

The resistor 51A and the resistor 51B are connected to the coil 21C as in FIG. 1. The resistor 51A and the resistor 51B are disposed outside the CMNF 20C.

A first end of the coil 21D is connected to a first end of a resistor 53A. A second end of the resistor 53A is connected to GND. A second end of the coil 21D is connected to a first end of a resistor 53B. A second end of the resistor 53B is connected to GND. The resistor 53A and the resistor 53B are disposed not inside the CMNF 20C but outside the CMNF 20C.

By this configuration, in the common mode, an electromagnetic field is applied to the coil 21C and the coil 21D, and an induced electromotive force is generated in the coil 21C and the coil 21D. The current generated in the coil 21C and the coil 21D by the induced electromotive force is consumed as heat in the resistor 51A, the resistor 51B, the resistor 53A, and the resistor 53B connected to the outside of the CMNF 20C. Accordingly, similarly to the case in FIG. 1 described above, the reflection of the common mode noise can be prevented.

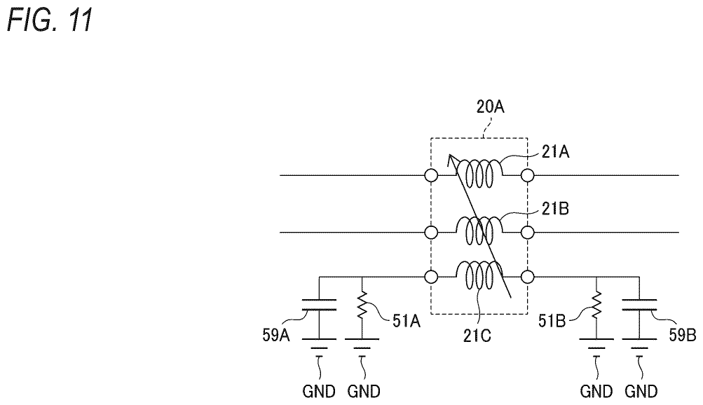

FIG. 11 is a diagram showing a second modification of a configuration of a CMNF and resistors according to Embodiment 1. FIG. 11 shows a configuration of an equivalent circuit of the CMNF and the resistors.

As shown in FIG. 11, the first end of the coil 21C of the CMNF 20A shown in FIG. 1 may be connected to GND via the resistor 51A and also connected to GND via a capacitor 59A. The second end of the coil 21C of the CMNF 20A may be connected to GND via the resistor 51B and also connected to GND via a capacitor 59B.

By this configuration, the current generated in the coil 21C by the induced electromotive force is consumed in the resistor 51A, the resistor 51B, the capacitor 59A, and the capacitor 59B. Accordingly, similarly to the case in FIG. 1 described above, the reflection of the common mode noise can be prevented.

### Embodiment 2

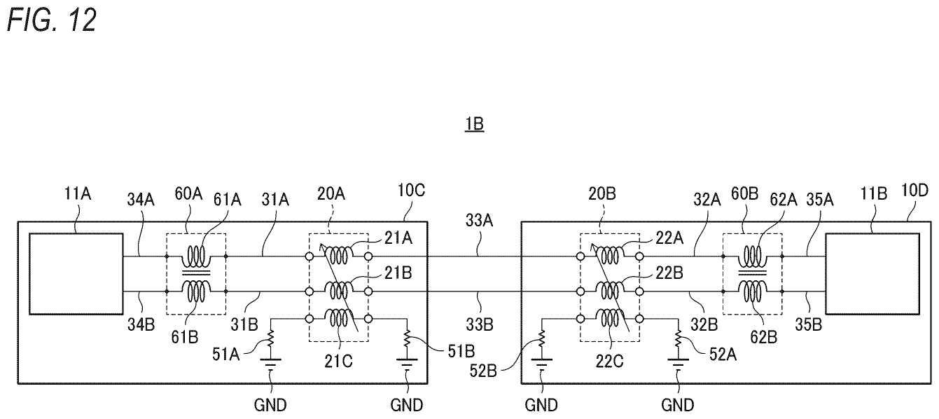

FIG. 12 is a diagram showing an example of a configuration of a communication system 1B according to Embodiment 2. FIG. 12 shows a configuration of an equivalent circuit of the communication system 1B.

The communication system 1B according to Embodiment 2 is different from communication system 1A according to Embodiment 1 shown in FIG. 1 in that the communication system 1B further includes a reflection CMNF 60A and a reflection CMNF 60B. In Embodiment 2, the same reference numerals are given to the components described in Embodiment 1, and the description thereof may be omitted.

A communication device 10C includes the reflection CMNF 60A positioned between the communication control circuit 11A and the CMNF 20A. That is, in a case in which a side closer to the communication control circuit 11A is referred to as a “front portion” and a side farther from the communication control circuit 11A is referred to as a “rear portion” when viewed from the CMNF 20A, the reflection CMNF 60A is disposed at the front portion of the CMNF 20A. The communication device 10C further includes a line 34A and a line 34B.

The reflection CMNF 60A includes a coil 61A and a coil 61B. The coil 61A and the coil 61B are wound in the same direction and configured to be magnetically coupled to each other.

A first end of the line 34A is connected to the communication control circuit 11A, and a second end of the line 34A is connected to a first end of the coil 61A of the reflection CMNF 60A.

A first end of the line 34B is connected to the communication control circuit 11A, and a second end of the line 34B is connected to a first end of the coil 61B of the reflection CMNF 60A.

The first end of the line 31A is connected to a second end of the coil 61A of the reflection CMNF 60A, and the second end of the line 31A is connected to the first end of the coil 21A of the CMNF 20A.

The first end of the line 31B is connected to a second end of the coil 61B of the reflection CMNF 60A, and the second end of the line 31B is connected to the first end of the coil 21B of the CMNF 20A.

A communication device 10D includes a reflection CMNF 60B positioned between the communication control circuit 11B and the CMNF 20B. That is, in a case in which a side closer to the communication control circuit 11B is referred to as a “front portion” and a side farther from the communication control circuit 11B is referred to as a “rear portion” when viewed from the CMNF 20B, the reflection CMNF 60B is disposed at the front portion of the CMNF 20B. The communication device 10D further includes a line 35A and a line 35B.

The reflection CMNF 60B includes a coil 62A and a coil 62B. The coil 62A and the coil 62B are wound in the same direction and configured to be magnetically coupled to each other.

A first end of the line 35A is connected to the communication control circuit 11B, and a second end of the line 35A is connected to a first end of the coil 62A of the reflection CMNF 60B.

A first end of the line 35B is connected to the communication control circuit 11B, and a second end of the line 35B is connected to a first end of the coil 62B of the reflection CMNF 60B.

The first end of the line 32A is connected to a second end of the coil 62A of the reflection CMNF 60B, and the second end of the line 32A is connected to the first end of the coil 22A of the CMNF 20B.

The first end of the line 32B is connected to a second end of the coil 62B of the reflection CMNF 60B, and the second end of the line 32B is connected to the first end of the coil 22B of the CMNF 20B.

The line 34A, the coil 61A of the reflection CMNF 60A, the line 31A, the coil 21A of the CMNF 20A, the line 33A, the coil 22A of the CMNF 20B, the line 32A, the coil 62A of the reflection CMNF 60B, and the line 35A may be referred to as a first transmission line. The line 34B, the coil 61B of the reflection CMNF 60A, the line 31B, the coil 21B of the CMNF 20A, the line 33B, the coil 22B of the CMNF 20B, the line 32B, the coil 62B of the reflection CMNF 60B, and the line 35B may be referred to as a second transmission line. The first transmission line and the second transmission line may be collectively referred to as a differential transmission line.

By providing the reflection CMNF 60A, the common mode noise directed to the communication control circuit 11A in the line 31A and the line 31B is reflected by the reflection CMNF 60A and returns to the CMNF 20A. The reflected common mode noise is consumed as heat in the resistor 51A and the resistor 52A connected to the coil 21C of the CMNF 20A as described in Embodiment 1. Therefore, the configuration of the communication device 10C including the reflection CMNF 60A shown in FIG. 12 can further prevent the emission of the common mode noise as compared with the configuration of the communication device 10A shown in FIG. 1. The same applies to the communication device 10D including the reflection CMNF 60B.

### Verification for Transmission Characteristic

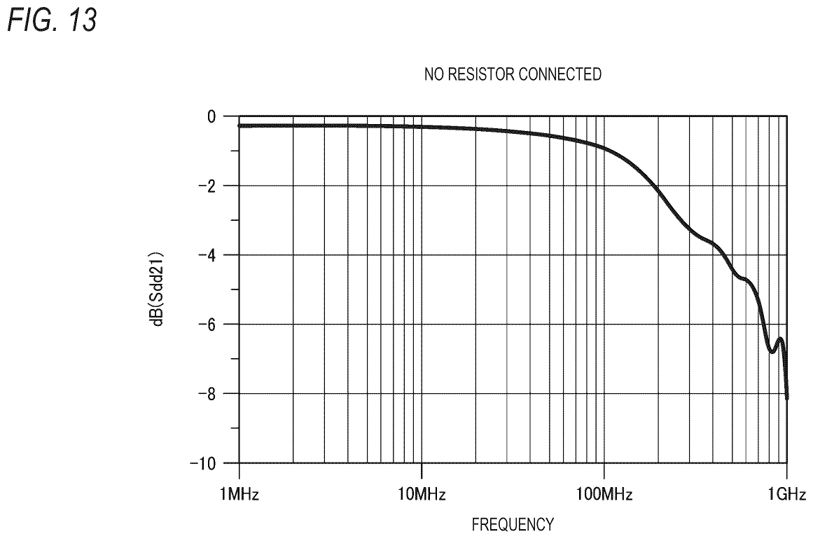

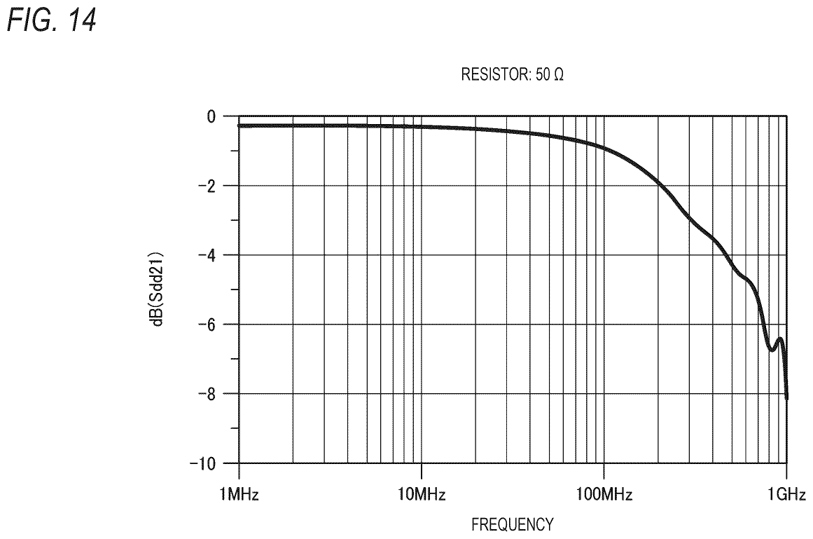

Next, with reference to FIGS. 13 and 14, it will be described that the configurations of the communication device 10C and the communication device 10D shown in FIG. 12 are less likely to affect the transmission characteristic of the differential transmission line.

FIG. 13 is a graph showing the transmission characteristic of the differential transmission line in a configuration in which the resistor 51A and the resistor 51B of the communication device 10C shown in FIG. 12 are not disposed. FIG. 14 is a graph showing the transmission characteristic of the differential transmission line in a configuration in which the resistor 51A and resistor 51B are disposed in the communication device 10C as shown in FIG. 12. In the graphs shown in FIGS. 13 and 14, a horizontal axis represents frequency, and a vertical axis represents intensity of the transmission characteristic. FIG. 14 is a graph when the resistance value of the resistor 51A and the resistor 51B is 50Ω.

When FIG. 13 and FIG. 14 are compared, the transmission characteristic is almost unchanged between a case in which the resistor 51A and the resistor 51B are not disposed and a case in which the resistor 51A and the resistor 51B are disposed. That is, it can be seen that even when the resistor 51A and the resistor 51B are disposed, the transmission characteristic is less likely to be affected.

### Verification for Resistance Value

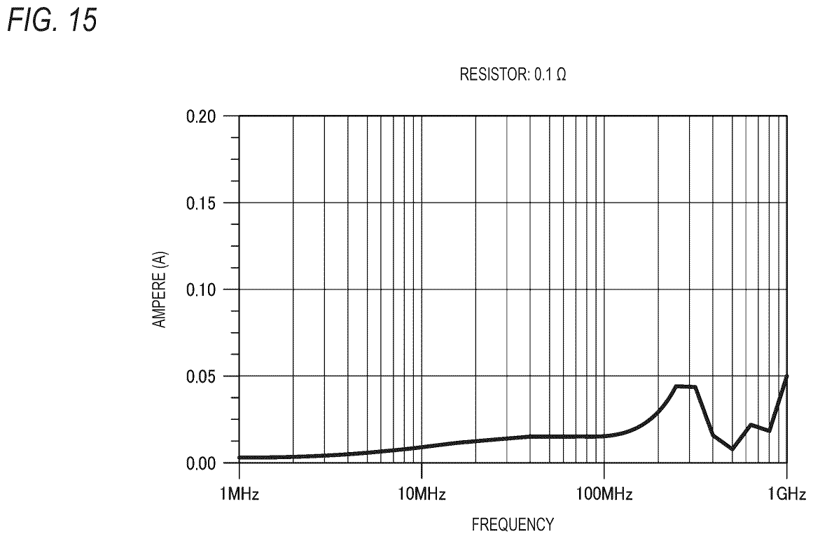

Next, a relation between the resistance value of the resistor 51A and resistor 51B and an effect of preventing the common mode noise will be described with reference to FIGS. 15 to 20.

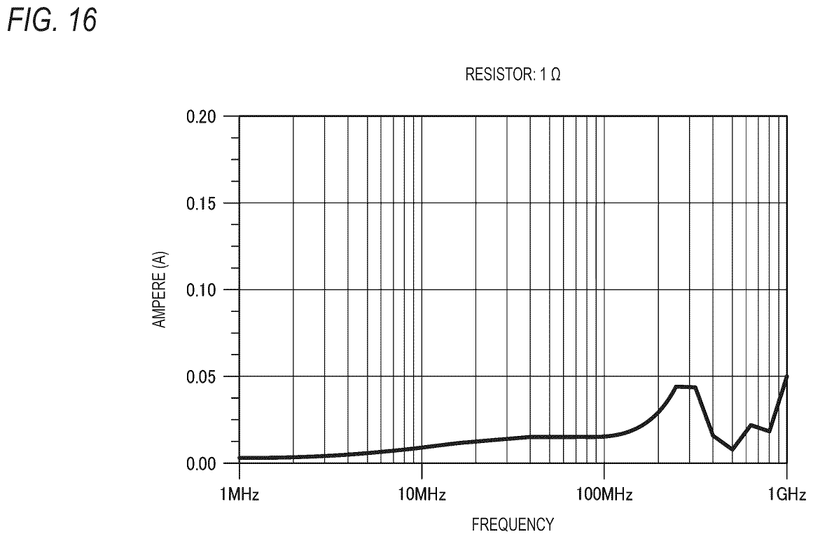

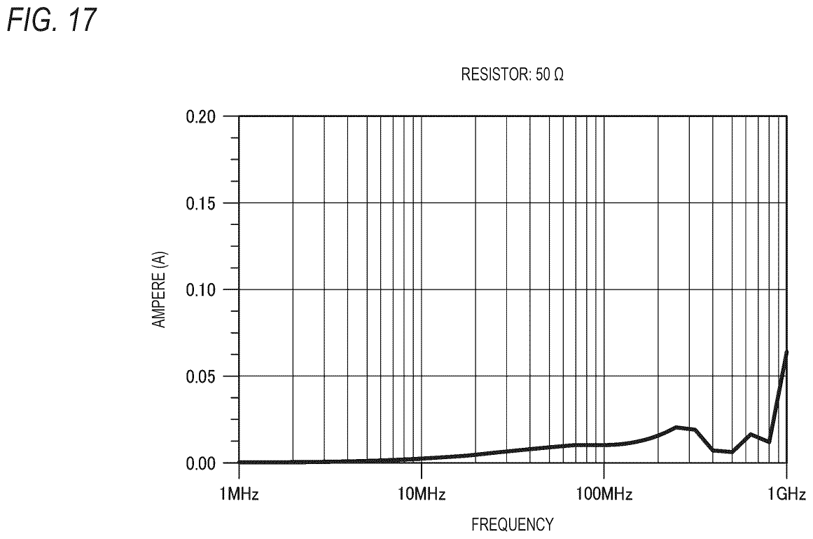

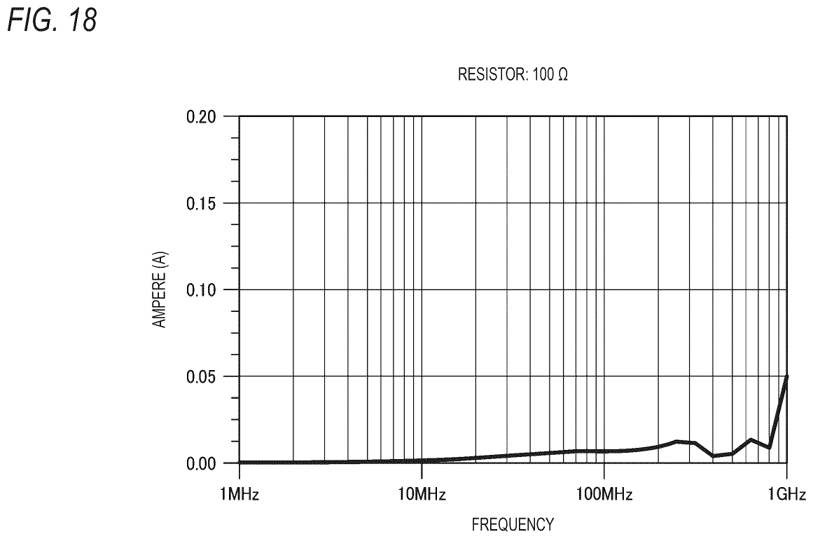

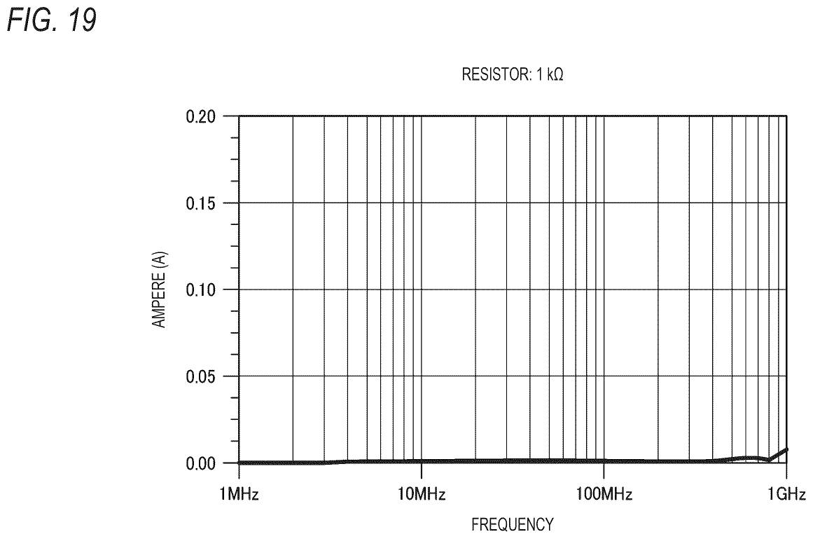

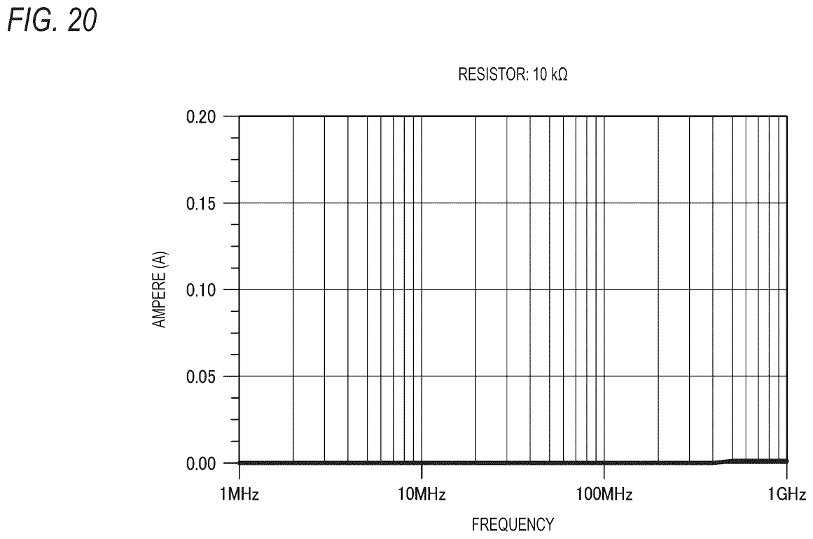

FIG. 15 is a graph showing a value of current flowing through the resistor 51A and the resistor 51B when the resistance value of the resistor 51A and the resistor 51B is 0.1Ω in the configuration of the communication system 1B shown in FIG. 12. FIG. 16 is a graph showing a value of current flowing through the resistor 51A and the resistor 51B when the resistance value of the resistor 51A and the resistor 51B is 1Ω in the configuration of the communication system 1B shown in FIG. 12. FIG. 17 is a graph showing a value of current flowing through the resistor 51A and the resistor 51B when the resistance value of the resistor 51A and the resistor 51B is 50Ω in the configuration of the communication system 1B shown in FIG. 12. FIG. 18 is a graph showing a value of current flowing through the resistor 51A and the resistor 51B when the resistance value of the resistor 51A and the resistor 51B is 100Ω in the configuration of the communication system 1B shown in FIG. 12. FIG. 19 is a graph showing a value of current flowing through the resistor 51A and the resistor 51B when the resistance value of the resistor 51A and the resistor 51B is 1 kΩ in the configuration of the communication system 1B shown in FIG. 12. FIG. 20 is a graph showing a value of current flowing through the resistor 51A and the resistor 51B when the resistance value of the resistor 51A and the resistor 51B is 10 kΩ in the configuration of the communication system 1B shown in FIG. 12. In each of the graphs shown in FIGS. 15 to 20, a horizontal axis represents frequency, and a vertical axis represents the current value (ampere).

As shown in FIGS. 15 to 19, it can be seen that in a case in which the resistance value of the resistor 51A and the resistor 51B is 0.1Ω to 1 kΩ, when the common mode noise of 100 MHz or more occurs, the induced electromotive force is generated in the coil 21C and the current flows through the resistor 51A and the resistor 51B. That is, it can be seen that the reflection of the common mode noise is prevented by consuming the common mode noise as heat by the resistor 51A and the resistor 51B.

Further, as compared with the graphs of FIGS. 4 to 8, it can be seen that more current flows through the resistor 51A and the resistor 51B in the graph of FIGS. 15 to 19. From this, it can be seen that by providing the reflection CMNF 60A as shown in FIG. 12, reflection of more common mode noise can be prevented as compared with a configuration without the reflection CMNF 60A as shown in FIG. 1.

It can be seen that even when the resistance value of the resistor 51A and the resistor 51B connected to the coil 21C of the CMNF 20A is a relatively small value such as 0.1Ω, a sufficient effect of preventing the reflection of the common mode noise is exhibited.

As shown in FIG. 20, when the resistance value of the resistor 51A and resistor 51B is 10 kΩ, almost no current flows through the resistor 51A and resistor 51B.

That is, in the configuration of the communication device 10C shown in FIG. 12, the resistance value of the resistor 51A and the resistor 51B may be in a range of more than 0Ω and 1 kΩ or less. However, the resistance value of the resistor 51A and the resistor 51B are not limited to the range. The same applies to the resistor 52A and the resistor 52B of the communication device 10D.

### Modification

The communication system 1B is not limited to the configuration shown in FIG. 12, and may be configured as, for example, any one of the following (A1) to (A2). As described above, the side closer to the communication control circuit 11A is referred to as the “front portion” and the side farther from the communication control circuit 11A is referred to as the “rear portion” when viewed from the CMNF 20A. The side closer to the communication control circuit 11B is referred to as the “front portion” and the side farther from the communication control circuit 11B is referred to as the “rear portion” when viewed from the CMNF 20B.

(A1) In the communication device 10C, the reflection CMNF 60A may be disposed at the rear portion of the CMNF 20A. (A2) In the communication device 10D, the reflection CMNF 60B may be disposed at the rear portion of the CMNF 20B.

### Summary of Present Disclosure

The following techniques are disclosed based on the above description of the present disclosure.

### Technique 1

A communication device (10A) that performs data transmission according to a differential transmission method according to an aspect of the present disclosure includes: a first common mode noise filter (20A) including a first coil (21A), a second coil (21B), and a third coil (21C); a communication control circuit (11A) configured to transmit and receive a signal through a first line (31A) connected to the first coil and a second line (31B) connected to the second coil; and at least one resistor (51A, 51B) having a first end connected to the third coil and a second end connected to GND, and configured to be disposed outside the first common mode noise filter.

Accordingly, the common mode noise is generated as the current in the third coil by the induced electromotive force. The current generated in the third coil is consumed as the heat in the resistor. As a result, the common mode noise is absorbed and reduced. In addition, the resistor is disposed outside the first common mode noise filter, and thus the heat generated by the resistor is less likely to affect the first common mode noise filter. Therefore, it is possible to achieve a communication device including a common mode noise filter and having improved heat resistance.

### Technique 2

In the communication device according to Technique 1, the at least one resistor includes: a first resistor (51A) connected to a first end of the third coil; and a second resistor (52B) connected to a second end of the third coil.

Accordingly, the common mode noise can be effectively absorbed and reduced.

### Technique 3

In the communication device according to Technique 2, a resistance value of the first resistor is equal to a resistance value of the second resistor.

Accordingly, the common mode noise can be effectively absorbed and reduced.

### Technique 4

In the communication device according to Technique 3, the resistance value of the first resistor is more than 0Ω and 1 kΩ or less.

Accordingly, the common mode noise signal can be effectively absorbed and reduced.

### Technique 5

The communication device according to any one of Techniques 1 to 4, further includes a second common mode noise filter (60A) that is disposed in a front portion closer to the communication control circuit (11A) than to the first common mode noise filter or in a rear portion farther from the communication control circuit (11A) than the first common mode noise filter and that includes at least two coils (61A, 61B).

Accordingly, the common mode noise is reflected by the second common mode noise filter and returns to the first common mode noise filter. The reflected common mode noise is also consumed as heat by the resistor connected to the third coil of the first common mode noise filter. Therefore, the common mode noise can be further absorbed and reduced.

Although the embodiments have been described above with reference to the accompanying drawings, the present disclosure is not limited thereto. It is apparent to those skilled in the art that various modifications, corrections, substitutions, additions, deletions, and equivalents can be conceived within the scope described in the claims, and it is understood that such modifications, corrections, substitutions, additions, deletions, and equivalents also fall within the technical scope of the present disclosure. In addition, components in the embodiment described above may be combined freely in a range without departing from the gist of the invention.

### INDUSTRIAL APPLICABILITY

The techniques of the present disclosure are useful for preventing the common mode noise.

### CROSS-REFERENCE TO RELATED APPLICATIONS

This application is based on and claims priority under 35 USC 119 from Japanese Patent Application No. 2024-208959 filed on Nov. 29, 2024, the contents of which are incorporated herein by reference.

What is claimed is:

1. A communication device that performs data transmission according to a differential transmission method, the communication device comprising:
a first common mode noise filter including a first coil, a second coil, and a third coil;
a communication control circuit that transmits and receives a signal through a first line connected to the first coil and a second line connected to the second coil; and
at least one resistor that has a first end connected to the third coil and a second end connected to GND, and that is disposed outside the first common mode noise filter.

2. The communication device according to claim 1, wherein
the at least one resistor includes a first resistor connected to a first end of the third coil, and a second resistor connected to a second end of the third coil.

3. The communication device according to claim 2, wherein
a resistance value of the first resistor is equal to a resistance value of the second resistor.

4. The communication device according to claim 3, wherein
the resistance value of the first resistor is more than 0Ω and 1 kΩ or less.

5. The communication device according to claim 1, further comprising:
at least one second common mode noise filter that includes at least two coils, and that is disposed in a front portion closer to the communication control circuit than to the first common mode noise filter or in a rear portion farther from the communication control circuit than the first common mode noise filter.

6. The communication device according to claim 2, wherein
a resistance value of the first resistor is different from a resistance value of the second resistor.

7. The communication device according to claim 2, wherein
at least one of a resistance value of the first resistor and a resistance value of the second resistor is 0Ω.

8. The communication device according to claim 1, wherein
the first common mode noise filter further includes a fourth coil, and
the communication device further includes at least one second resistor that has a first end connected to the fourth coil and a second end connected to GND and that is disposed outside the first common mode noise filter.

9. The communication device according to claim 2, wherein
each of the first resistor and the second resistor is connected in parallel with a capacitor.

10. The communication device according to claim 1, wherein
the first coil and the second coil are wound in the same direction, and
the first coil the second coil, and the third coil are configured to be magnetically coupled to each other.

11. The communication device according to claim 5, wherein
the at least one second common mode noise filter includes two second common mode noise filters and one of the two second common mode noise filters is disposed in the front portion and the other of the two second common mode noise filters is disposed in the rear portion.
